(19) United States
(12) Patent Application Publication
(10) Pub. No.: US 2009/0248332 A1
(43) Pub. Date: Oct. 1, 2009

(54) Maximizing Battery Life

(75) Inventors: Paul William Calnan, III, Somerville, MA (US); John Mastroianni, Hopkinton, MA (US); Rob Podoloff, Framingham, MA (US)

Correspondence Address: FISH & RICHARDSON, PC, P.O. BOX 1022, MINNEAPOLIS, MN, 55440-1022, US

(73) Assignee: ZEEMOTE, INC., Bedford, MA (US)

(21) Appl. No.: 12/060,100

(22) Filed: Mar. 31, 2008

(51) Int. Cl. G01R 31/36; G01R 19/00

(52) U.S. Cl. 702/63; 702/64

(57) ABSTRACT

Maximizing battery life includes identifying a characteristic curve for a voltage regulating component. A raw voltage value of a battery associated with the voltage regulating component or power converting component is detected. A mathematical model is generated based on the identified characteristic curve. In addition, a value of a regulated voltage output of the voltage regulating component or a converted voltage output of the power converting component is predicted by using the generated mathematical model to convert the detected raw voltage value of the battery.

### TECHNICAL FIELD

This disclosure is directed to battery powered devices.

### BACKGROUND

Battery operated electronic devices may find it difficult to maintain a high level of performance as the battery voltage starts to drop from prolonged use. The performance of various electronic components in the circuitry of the device can start to deteriorate as the battery voltage continues to drop.

### SUMMARY

Implementations of techniques, systems and computer program products described in this specification for maximizing battery life while maintaining the operational integrity of the electronic components in a circuitry may include various combinations of the following features.

Maximizing battery life includes identifying a characteristic curve for a voltage regulating component. A raw voltage value of a battery associated with the voltage regulating component or power converting component is detected. A mathematical model is generated based on the identified characteristic curve. In addition, a value of a voltage output of the voltage regulating component is predicted by using the generated mathematical model to convert the detected raw voltage value of the battery.

Implementations can optionally include one or more of the following features. The detected raw voltage value of the battery can be monitored throughout a life of the battery to detect a change in the detected raw voltage value. Based on the detected change, the predicted value can be recalculated. Also the value of the regulated voltage or the converted voltage used to power an electronic component associated with the voltage regulating component can be predicted. Predicting the value includes predicting the value of the voltage output used to power the electronic component including a user input component. In addition, an output voltage at a terminal of a position sensing component included in the user input component can be calculated based on the predicted value of the voltage output of the voltage regulating component. The calculated output voltage represents a measure of a position for the position sensing component. The position sensing component can include a potentiometer. An output voltage can be calculated at a terminal of a potentiometer included in the user input component based on the predicted value of the voltage output of the voltage regulating component. The calculated output voltage represents a measure of a position for the potentiometer. Alternatively, the position sensing component can include an accelerometer. An output voltage can be calculated at a terminal of an accelerometer included in the user input component based on the predicted value of the voltage output of the voltage regulating component. The calculated output voltage represents a measure of a position for the accelerometer.

In another aspect, a computer program product, embodied on a computer readable medium, can be operable to cause a data processing apparatus to perform various operations. For example, the computer program product is operable to cause a data processing apparatus to identify a characteristic curve for a voltage regulating component. The computer program product is also operable to cause a data processing apparatus to detect a raw voltage value of a battery associated with the voltage regulating component. In addition, the computer program product is operable to cause a data processing apparatus to generate a mathematical model based on the identified characteristic curve. Further, the computer program product is operable to cause a data processing apparatus to predict a value of a voltage output of the voltage regulating component by using the generated mathematical model to convert the detected raw voltage value of the battery.

Implementations can optionally include one or more of the following features. The computer program product can be operable to cause a data processing apparatus to perform operations including monitoring the detected raw voltage value of the battery throughout a life of the battery to detect a change in the detected raw voltage value; and recalculating based on the detected change. The computer program product can be operable to cause a data processing apparatus to perform operations including predicting the value of the voltage output used to power an electronic component associated with the voltage regulating component. The computer program product can be operable to cause a data processing apparatus to perform operations including powering a user input component. The computer program product can be operable to cause a data processing apparatus to perform operations including calculating an output voltage at a terminal of a position sensing component included in the user input component based on the predicted value of the voltage output of the voltage regulating component. The calculated output voltage represents a measure of a position for the position sensing component. The position sensing component can include a potentiometer. In such implementations, the computer program product can be operable to cause a data processing apparatus to perform operations including calculating an output voltage at a terminal of the potentiometer included in the user input component based on the predicted value of the voltage output of the voltage regulating component. The calculated output voltage represents a measure of a position for the potentiometer. Alternatively, the position sensing component can include an accelerometer. In such implementations, the computer program product can be operable to cause a data processing apparatus to perform operations including calculating an output voltage of the accelerometer included in the user input component based on the predicted value of the voltage output of the voltage regulating component. The calculated output voltage represents a measure of a position for the accelerometer.

In another aspect, a device includes a battery, a voltage regulating component connected to the battery and a processor connected to the battery and the voltage regulating component. The processor is configured to process software or firmware to perform various operations. For example, the processor can detect a characteristic curve for the voltage regulating component. The processor can detect a raw voltage value of the battery connected to the voltage regulating component. Also, the processor can process a mathematical model generated based on the identified characteristic curve to predict a value of a voltage output of the voltage regulating component by using the generated mathematical model to convert the detected raw voltage value of the battery.

Implementations can optionally include one or more of the following features. The processor can monitor the detected raw voltage value of the battery throughout a life of the battery to detect a change in the detected raw voltage value; and recalculating the predicted value based on the detected change. The device can include an electronic component connected to the voltage regulating component, and the processor can be operable to predict the voltage output used to power the electronic component associated with the voltage regulating component. The processor can be operable to predict the voltage used to power the electronic component including a user input component. The electronic component can include a position sensing component, and the processor can be operable to calculate an output voltage at a terminal of the position detecting component based on the predicted value of the voltage output of the voltage regulating component. The calculated output voltage represents a measure of a position for the position sensing component. The position sensing component can include a potentiometer, and the processor can be operable to calculate an output voltage of the potentiometer based on the predicted value of the voltage output of the voltage regulating component. The calculated output voltage represents a measure of a position for the potentiometer. The position sensing component can include an accelerometer, and the processor can be operable to calculate an output voltage of the accelerometer based on the predicted value of the voltage output of the voltage regulating component. The calculated output voltage represents a measure of a position for the accelerometer. The voltage regulating component can include a linear voltage regulator. Also, the power converting component can include a digital to digital converter.

The subject matter described in this specification potentially may provide one or more of the following advantages. For example, the described techniques for using a software or firmware model to predict the output voltage of a voltage regulating device as a function of changing battery voltage enables a battery operated device to be run on the same set of batteries for a substantially longer period of time while maintaining the accuracy of output and integrity of operation of electronic components on a circuit board of the device. Then the printed circuit board (PCB) can be designed to utilize lower cost components and can result in a lower cost of goods sold. The potential benefit to the end user can be even more tangible. A battery can be used to power the same device for a much longer period of time while maintaining accuracy of output. If the batteries are rechargeable, the user can use the device for longer periods of time without recharging. If the batteries are not rechargeable, the user can buy fewer batteries, resulting in a lower out of pocket cost and a more environmentally friendly approach to operating battery powered devices.

In addition, the subject matter described in this specification can be implemented as a system including a processor and a memory coupled to the processor. The memory may encode one or more programs that cause the processor to perform one or more of the method acts described in this specification. Further, the subject matter described in this specification can be implemented using various data processing machines.

Details of one or more implementations are set forth in the accompanying drawings and the description below. Other features and advantages will be apparent from the description and drawings, and from the claims.

### DESCRIPTION OF DRAWINGS

FIG. 1 shows a schematic of an example potentiometer.

FIG. 2 shows an example process for modeling an output voltage from a voltage regulating component as a function of a battery voltage.

FIG. 3 is a block diagram showing an example system for predicting an output voltage of a voltage regulating device.

FIG. 4 shows an example characteristic curve outlining a relationship between regulated voltage V_{REGULATED} and raw battery voltage V_{BATT} for a linear voltage regulator.

FIG. 5 shows an example characteristic curve outlining a relationship between regulated voltage V_{REGULATED} and raw battery voltage V_{BATT} for a DC to DC converter.

FIG. 6 shows an example process for generating a function to accurately estimate a value of V_{DD}_{_{—}}_{ANALOG} based on a value of V_{BATT}.

FIG. 7 shows an example schematic diagram for the potentiometer behaving as a voltage divider.

### DETAILED DESCRIPTION

Techniques, systems and computer program products are described in this specification for maximizing battery life while maintaining the operational integrity of the electronic components in a circuitry.

Electronic circuitry powered by a battery tends to make use of a voltage regulating component to obtain a regulated voltage from the battery. A voltage regulating component is an electrical regulator designed to automatically maintain a constant voltage level. The voltage regulating component can include variety of components including an alternating current (AC) voltage stabilizer, a direct current (DC) stabilizer, a linear regulator, a switching regulator, etc. The voltage regulating component also includes power converting components that convert an electric power from one form to another form. Power converters can include variety of component including DC to DC converters, AC to DC converters, DC to AC converters, and AC to AC converters.

For example, a voltage regulating component, such as a linear voltage regulator or a DC to DC converter, can be used to convert the raw battery voltage (V_{BATT}) to a consistent, regulated voltage (V_{REGULATED}). This regulated or converted voltage is then used to power the electronic components on the electronic circuitry. These electronic components are designed to operate to their specifications if the source voltage is held constant.

However, the output of a voltage regulating component may not remain constant throughout the life of a battery. A characteristic curve that is unique to the voltage regulating component may govern the relationship between the V_{BATT} and V_{REGULATED}, and that relationship is at least partially driven by the solid state physics of a semiconductor chip that includes the electronic circuitry to be powered by the battery.

Eventually, the regulated output voltage or the converted voltage of the voltage regulating component from such battery powered electronic circuitry may dip quite dramatically as V_{BATT} drops with continued use. This can become a significant source of error in the operation of the electronic components included in the electronic circuitry.

For wired devices, such error is typically not a problem as the voltage from a non-battery power supply remains relatively constant and does not dip over time. Consequently, the regulated voltage from the power supply also will not dip. For battery powered devices, such consistent and trustworthy power supply is lacking. Thus, product designers of battery powered devices may be forced to implement a design that cuts off the battery powered device at a relatively high battery voltage threshold to maintain the integrity of the device's operation. Such design can result in a shortened battery life time or lead to performance deterioration of certain electronic components over time in order to prolong the battery life. Attempts to implement a hardware solution to maintain V_{REGULATED} at a constant voltage can be faced with numerous disadvantages including the need for additional components, additional power consumption, and higher cost.

An example class of electrical components that can suffer significantly from a degradation of the output voltage of a voltage regulating device include position or motion sensing components that transform motions into electrical currents and/or voltages to obtain motion or position information. For example, potentiometers can be used as position sensors, the positions of which are read by analog-to-digital converters. A potentiometer is a ubiquitous sensor that is used in a wide variety of applications where continuous positional measurements are desired. A potentiometer can be a three-terminal resistor with a sliding contact that forms an adjustable voltage divider. Typically, the two terminals on each end are connected to a reference voltage and a ground or common voltage, and the middle terminal represents the output voltage on the wiper. The base of the potentiometer is typically mounted on a mechanism, and the wiper is typically mechanically coupled to a moving member in the mechanism such that the movement of the member will be measured by a changing output voltage on the wiper.

Example applications for a potentiometer based sensor include various user input mechanisms such as dials and knobs, sliders, rotary sensors embedded in joints in articulated linkage mechanisms such as robots or multiple-degree-of-freedom position and orientation sensing devices, and in two or three degree of freedom joysticks. Further, consumer grade gaming controllers designed to work with a gaming platform such as a personal computer (PC), a console (including the Sony® PlayStation®, PlayStation® 2, PlayStation® 3, the Microsoft® Xbox® and Xbox® 360, and the Nintendo® Wii® Nunchuck controller, among others), a TV gaming device (such as a Radica Play TV), a hand held gaming device (such as the Sony® PlayStation® Portable) all use potentiometers as a positional sensor.

Some of these gaming controller devices are wired so that the components of the devices receive power from a plug in connection to the gaming platform, whether a USB port on a PC or a gaming port on a controller. Others can include wireless devices that enable the controllers to communicate with the gaming platform wirelessly or the device itself may be a portable handheld gaming platform.

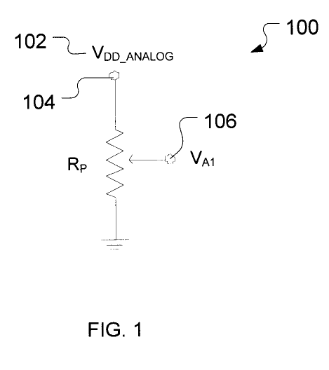

FIG. 1 shows a schematic of an example potentiometer. Wireless devices as described above are powered by one or more batteries. Among the many challenges of power conservation in battery operated devices, the accuracy of the potentiometer reading is a primary concern. As described above, the battery voltage V_{BATT} is typically converted into a regulated voltage V_{REGULATED} via a voltage regulating device such as a linear voltage regulator or a DC-to-DC converter. V_{REGULATED} is typically used as the reference voltage V_{DD}_{_{—}}_{ANALOG} 102 used to power the analog to digital converter (ADC) and one terminal 104 on the potentiometer 100.

The accuracy of the output voltage at the middle terminal, V_{AI} 106, as a measure of a position within the physical range of motion measured by the potentiometer is dependent on the accuracy of the reference voltage V_{DD}_{_{—}}_{ANALOG} 102. As the battery voltage V_{BATT} starts to fall, V_{DD}_{_{—}}_{ANALOG} 102 also falls. The change in V_{DD}_{_{—}}_{ANALOG} 102 relative to the change in battery voltage can be represented as a non-linear characteristic curve. Because V_{AI} 106 is monitored based on a reference voltage of V_{DD}_{_{—}}_{ANALOG} 102, at the same physical deflection, V_{AI} 106 will appear to start to fall.

For example, a deflection of 25 degrees out of 50 degrees can result in a V_{AI} 106 of 1.5V when V_{DD}_{_{—}}_{ANALOG} 102 is at 3.0 volts. The software or firmware acting on the output of the ADC will likely conclude that the potentiometer is at the midpoint of the operating range, which it should be.

But the same physical deflection of 25 degrees results in a V_{AI} of 1.25V when V_{DD}_{_{—}}_{ANALOG} is allowed to dip to 2.5V. With naïve reading of V_{AI} as an absolute positional measurement, the end result is an incorrect translation of V_{AI} to physical deflection. A physical deflection of 25 degrees in this scenario would be read as 20.8 degrees. The lower the V_{DD}_{_{—}}_{ANALOG} 102 is allowed to drift, the more exacerbated this problem becomes. A potential solution ca include turning off the device when the battery drops to such a level that causes erroneous readings of V_{AI}.

Other example applications can include output from an accelerometer. The reduction of battery voltage can also affect the voltage output of the accelerometer. Another example can include a typical circuit used to linearize a force sensitive resistor, or FSR. The FSR uses an inverting op-amp to regulate the voltage, and the output voltage of the inverting op-amp is a function of the supply voltage.

The subject matter as described in this specification can compensate for these potential errors caused by a voltage output of a voltage regulating component that changes as a function of the depleting battery voltage. In addition, the subject matter as described in this specification can maximize battery life while maintaining the operational integrity of the electronic components in a circuitry as the battery becomes depleted.

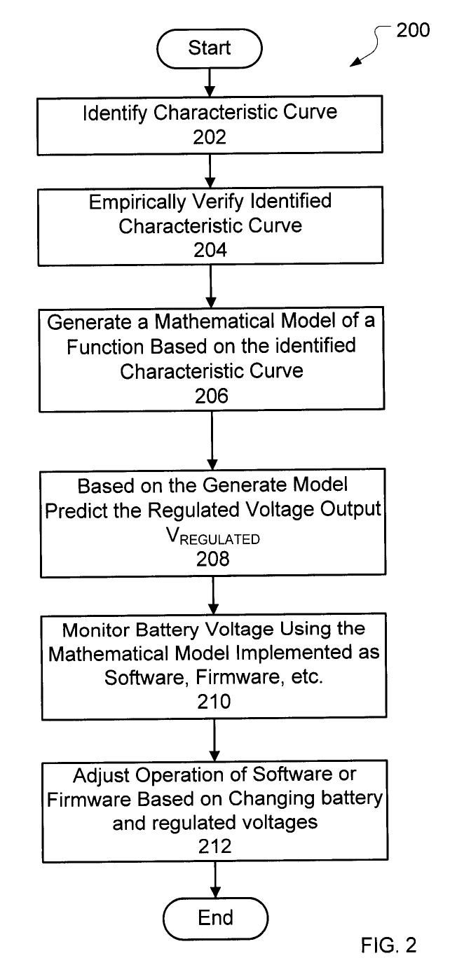

FIG. 2 shows an example process 200 for modeling an output voltage from a voltage regulating component as a function of a battery voltage. The characteristic curve representing the relationship between V_{REGULATED} and V_{BATT} is obtained 202 for the particular voltage regulating component. For example, the manufacturer of the voltage regulating component is identified, and the identified manufacturer's specification is reviewed. The obtained characteristic curve is verified 204 empirically. Based on the verified characteristic curve, a mathematical model of a function is generated 206 to convert the raw battery voltage V_{BATT} to the regulated voltage V_{REGULATED}. The calculated mathematical model is implemented in software or firmware. The calculated mathematical model can be implemented as a closed form equation, a lookup table or other similar mechanisms. Based on the generated mathematical model, predict 208 the regulated voltage output V_{REGULATED} from the voltage regulating component as a function of the battery voltage V_{BATT}. The battery voltage is monitored 210 within the software or firmware. Further, the operations of the software or firmware program are adjusted 212 based on changing battery voltage and predicted regulated voltage.

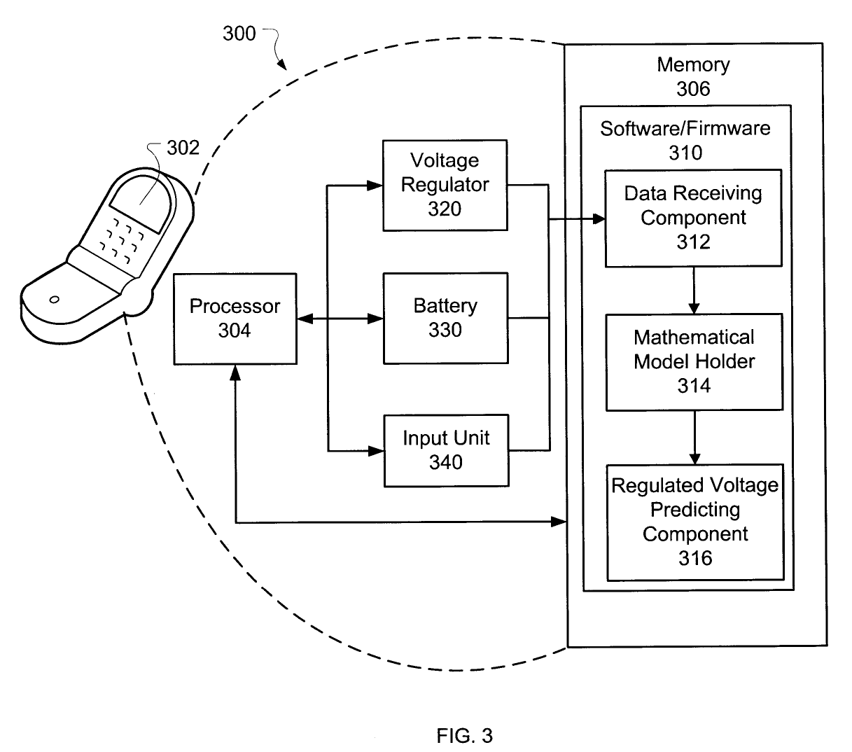

FIG. 3 is a block diagram showing an example system 300 for predicting an output voltage of a voltage regulating device. The system 300 includes a host device 302 that includes a wireless device. The wireless device may be any of a variety of devices, such as a mobile phone, a smart phone, a portable gaming device, a laptop, etc. The host device 302 can include various components including a processor 304 and a memory 306. The memory can include volatile and/or non-volatile memory devices.

Within the host device 302, software or firmware 310 can be embedded to predict an output voltage of a voltage regulating device. For example, the software or firmware 310 can be embedded in the memory 306. The software or firmware 310 can be implemented using one more components to accomplish various operations of the software or firmware 310. For example, the various components can include a data receiving component 312, a mathematical model holder 314 and a regulated voltage predicting component 316. However, in some implementations, these components 312, 314, 316 can be implemented as a single component. Alternatively, additional components can be implemented.

The data receiving component 312 can receive data from various components of the host device 302. For example, a voltage regulating component 320 can provide a regulated voltage V_{REGULATED} to the data receiving component 312. Also, a battery can provide its raw battery voltage V_{BATT} to the data receiving component 312. Additional components such as an input unit 340 can be connected to the data receiving component 312 to update the software or firmware, for example. Further, other information/data necessary for operation of the software or firmware 310 can be received through the input unit 340 or other components.

Once the data received from the voltage regulating component 320 and or 330 are processed to generate a mathematical model of a function as described with respect to FIG. 2 above and other portions of this specification, the generated model can be stored or embedded in the mathematical model holder 314. For example, the model is predetermined and hard coded into the firmware 310. The regulated voltage predicting component 316 can operate to use the embedded mathematical model to predict the regulated voltage V_{REGULATED} as described with respect to FIG. 2 and other portions of this specification.

The software or firmware 310 that includes the model can be used to predict the output voltage of a voltage regulating device (such as a linear voltage regulator or a DC-to-DC converter in battery operated electronic devices) to compensate for performance degradations of components in a circuitry of on a circuit board. The compensated performance degradations can be as a result of a drop in the battery voltage that causes a corresponding (and not necessarily linear) drop in the output voltage of the voltage regulating device.

This system 300 can be implemented for various electronic components. For example, the system 300 can be implemented to optimize the performance of potentiometers used as position sensors. The performance of the potentiometers are read by analog-to-digital converters (ADC) powered by the regulated voltage output of a voltage regulating device.

To compensate for the detrimental effects of battery depletion in a battery powered device, the output of the voltage regulating device, V_{REGULATED}, can be modeled as a function of the battery voltage, V_{BATT}, in software or firmware. This compensatory model can help to maintain a high quality of performance for electronic devices in circuitry or a circuit board even as the battery voltage dips below commonly accepted minimal thresholds. Further, such compensatory modeling can extend the operating life of the battery and improve end user experience for battery powered electronic devices.

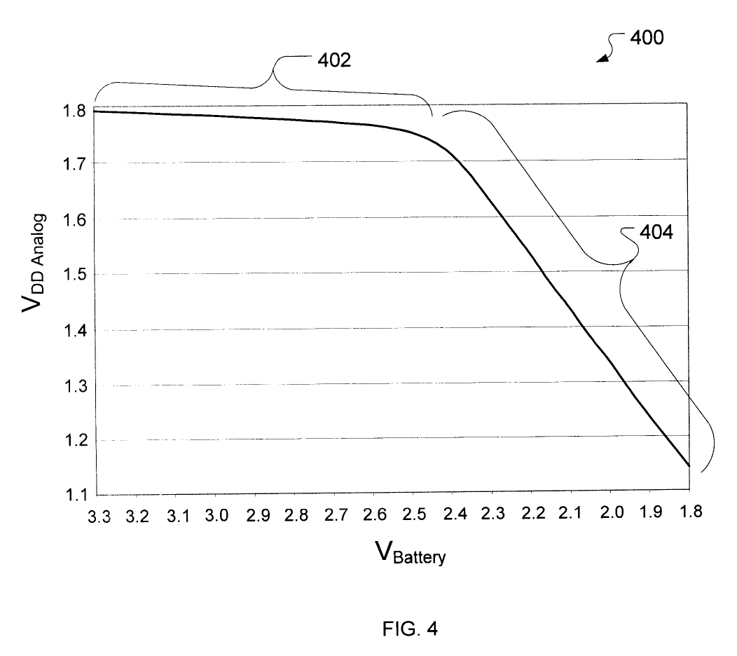

FIG. 4 shows an example characteristic curve 400 outlining a relationship between regulated voltage V_{REGULATED} and raw battery voltage V_{BATT} for a linear voltage regulator. For a wireless device, a voltage regulating component, such as a linear voltage regulator or a power converting component such as a DC-to-DC converter, generates V_{REGULATED} based on the raw voltage V_{BATT} supplied by a battery. As described above, V_{REGULATED} can be used as the reference voltage V_{DD}_{_{—}}_{ANALOG} to power an analog to digital converter (ADC) and one terminal on a potentiometer, for example.

The characteristic curve 400 shows the reference voltage V_{DD}_{_{—}}_{ANALOG} on the y-axis and the raw battery voltage V_{BATT} on the x-axis. When the battery is charged and the raw battery voltage V_{BATT} remains near full power, the reference voltage V_{DD}_{_{—}}_{ANALOG} remains relatively constant 402. However, as the battery begins to run low on voltage, the reference voltage V_{DD}_{_{—}}_{ANALOG} starts to decrease. The decrease in the reference voltage V_{DD}_{_{—}}_{ANALOG} accelerates 404 after the raw battery voltage V_{BATT} falls below a threshold level. For the example, shown in FIG. 4, the threshold raw battery voltage V_{BATT} is in the range of 2.6-2.4 volts.

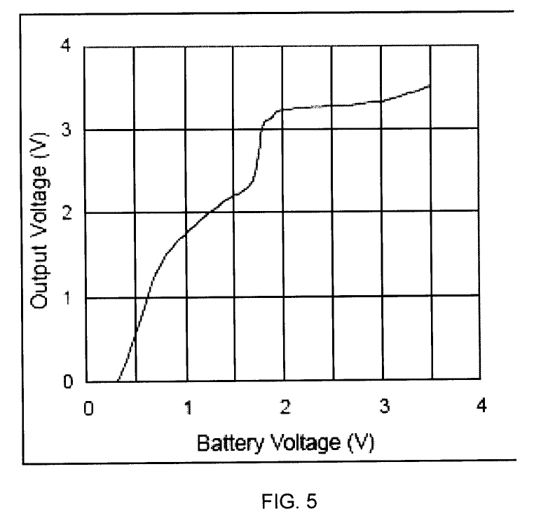

FIG. 5 shows an example characteristic curve 500 outlining a relationship between regulated voltage V_{REGULATED} and raw battery voltage V_{BATT} for a DC to DC converter. For the DC to DC converter example, the regulated voltage V_{REGULATED} is used as the output voltage V_{OUT} of the DC to DC converter. The example characteristic curve 500 for the DC to DC converter shows the output voltage V_{OUT} on the y-axis and the raw battery voltage V_{BATT} on the x-axis. The output voltage V_{OUT} falls as the raw battery voltage V_{BATT} decreases during usage. After the raw battery voltage V_{BATT} drops below a threshold level, near 2 volts for the example shown in FIG. 5, the decrease in the output voltage V_{OUT} accelerates dramatically.

These and other examples of characteristic curves can be quantified and embedded in software or firmware to predict the regulated voltage V_{REGULATED} generated from a particular voltage regulating component for a given battery voltage level. While the techniques, systems, etc. as described in this specification can be applied to various applications, only a few are provided for illustrative purposes.

For example, the techniques, systems, etc as described in this specification can be implemented for a device that uses an analog to digital converter (ADC) to detect a voltage, V_{AI}. This voltage V_{AI} can be obtained from the middle terminal of a potentiometer. The potentiometer's output voltage, V_{AI}, can be sampled by an n-bit ADC. The n-bit ADC measures V_{AI} relative to the device's internal supply voltage, V_{DD}_{_{—}}_{ANALOG}.

According to equation (1), a value r for the n-bit ADC can be calculated for a given raw battery voltage V_{BATT}.

$$r = \frac{{V}_{AI}}{{V}_{DD}} {2}^{n} \qquad ( 1 )$$

For each calculated value r, V_{AI} (in volts) can be calculated according to equation (2).

$${V}_{AI} = \frac{{rV}_{DD}}{{2}^{n}} \qquad ( 2 )$$

The detected value for the ADC can vary between 0 and 2n. This value can be used to determine the potentiometer's position between a minimum position, P_{MIN}, and a maximum position, P_{MAX}. Given a detected value r for the ADC, the corresponding position p can be calculated according to equation (3) if the potentiometer is linear.

$$p = {P}_{MIN} + \frac{r}{{2}^{n}} ( {P}_{MAX} - {P}_{MIN} ) \qquad ( 3 )$$

Due to the semiconductor physics of the linear voltage regulator, the DC-to-DC converter, or other such voltage regulating devices, V_{DD}_{_{—}}_{ANALOG} does not remain constant throughout the battery's voltage range. The value of V_{DD}_{_{—}}_{ANALOG} depends on the present battery voltage.

As shown in FIGS. 4-5, as the raw battery voltage depletes, V_{DD}_{_{—}}_{ANALOG} decreases steeply. The value of V_{AI} can range between 0 volts and the value of V_{DD}_{_{—}}_{ANALOG}. However, the position value of the potentiometer is determined using the ADC value based on V_{DD}_{_{—}}_{ANALOG}. Because the value of V_{DD}_{_{—}}_{ANALOG} changes with V_{BATT}, the detected value of ADC alone is insufficient to accurately determine the position of the potentiometer.

Referring back to FIG. 4 above, the value of V_{DD}_{_{—}}_{ANALOG} starts to drop off steeply after the threshold value is reached (approximately 2.4 volts in the example shown in FIG. 4.) As the value of V_{DD}_{_{—}}_{ANALOG} changes, the ADC reading for the potentiometer's center also changes. Thus, one potential solution is to mark the end of the battery's useful life at around 2.4 volts. In such example, the system may not be optimal because the system or device can continue to operate until the raw voltage for the battery reaches around 1.8 volts. Such solution results in a loss of 0.6 volts of battery life. This 0.6 volt may equate to several additional hours of battery life, for example.

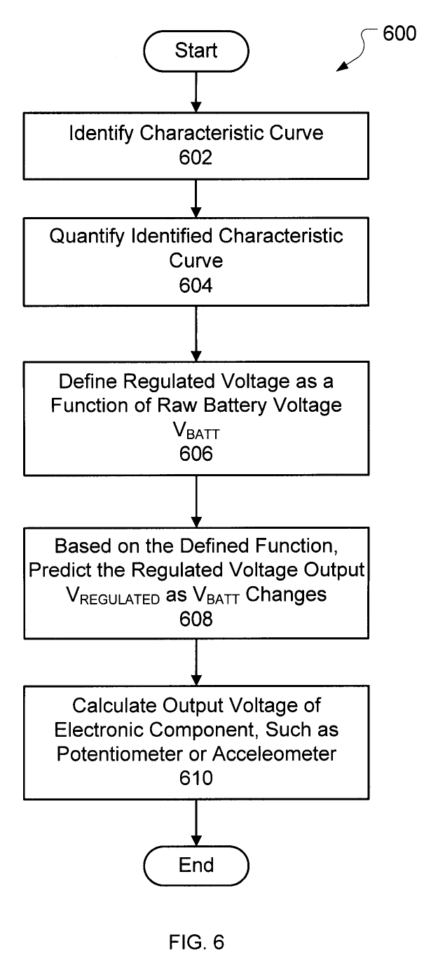

FIG. 6 shows an example process for generating a function to accurately estimate a value of V_{DD}_{_{—}}_{ANALOG} based on a value of V_{BATT}. This function depends on the behavior of the voltage regulating component used in the application. Also, this function can be estimated based on experimental data or on data provided by the manufacturer of the linear voltage regulator, DC-to-DC converter or other such device.

Once the characteristic curve, as shown in FIGS. 4 and 5, of the linear voltage regulator or DC-to-DC converter or similar voltage regulating component is determined 602, software or firmware can be designed to compute V_{DD}_{_{—}}_{ANALOG based on V}_{BATT}. The computed value can be calculated at runtime or stored in a lookup table, depending on the size and speed requirements of the application. The determined characteristic curve is quantified 604. Regulated voltage V_{REGULATED} is defined 606 as a function of raw battery voltage V_{BATT}. Based on the defined function, the regulated voltage V_{REGULATED} is predicted 608 dynamically as the raw battery voltage V_{BATT} changes (i.e., decreases). The regulated voltage V_{REGULATED} that is powering the one or more electronic components in a battery powered device is predicted. For example, the electronic component can include a potentiometer and/or accelerometer included in a joystick. The output voltage of the accelerometer and/or accelerometer is dependent of the predicted regulated voltage V_{REGULATED}.

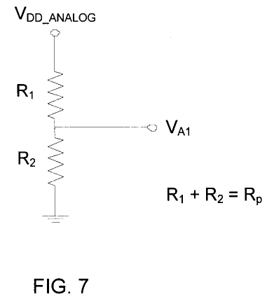

This software model of the characteristic curve can be implemented for the operation of a potentiometer as a position sensor. In a typical position sensing application, a potentiometer acts like a voltage divider. FIG. 7 shows an example schematic diagram for the potentiometer behaving as a voltage divider.

The position of the potentiometer can divide the resistive value of R_{P} of the potentiometer (in ohms) according to equation (4).

R_{P}=R₁+R₂ (4), where R₁ represents the resistance value of resistor R₁, and R₂ represents the resistance value of resistor R₂.

According to Ohm's Law, a voltage drop across a resistor can be calculated. Accordingly, the value of V_{AI} (in volts) can be calculated according to equation (5).

$${V}_{AI} = \frac{{R}_{2}}{{R}_{1} + {R}_{2}} {V}_{DD\_ANALOG} = \frac{{R}_{2}}{{R}_{1} + {R}_{2}} f ( {V}_{BATT} ) \qquad ( 5 )$$

Given V_{BATT} and an ADC reading r, R1 and R2 can be calculated. V_{DD}_{_{—}}_{ANALOG} is estimated based on V_{BATT} utilizing a software model of the characteristic curve governing the relationship between V_{DD}_{_{—}}_{ANALOG and V}_{BATT} for the particular voltage regulating device used in the circuit of interest. V_{DD}_{_{—}}_{ANALOG} is thus modeled in software or firmware as a function of V_{BATT}, or f(V_{BATT}).

The value of V_{AI} is calculated according to equation 2. Based on equations 4 and 5, the values for R1 and R2 (in ohms) can be calculated according to equations (6) and (7).

$$\begin{matrix}{R}_{1} = {R}_{P} - {R}_{2} & ( 6 ) \\ {R}_{2} = {R}_{P} - \frac{{R}_{P} {V}_{AI}}{{V}_{DD\_ANALOG}} = {R}_{P} - \frac{{R}_{P} {V}_{AI}}{f ( {V}_{BATT} )} & ( 7 )\end{matrix}$$

If the potentiometer is linear, the following expression as shown in equation (8) is true.

$$\frac{{R}_{1}}{{R}_{1} + {R}_{2}} = \frac{p}{{P}_{MAX} - {P}_{MIN}} \qquad ( 8 )$$

Solving for p, the position of the potentiometer can be detected based on the resistance values according to equation (9).

$$p = \frac{{R}_{1} ( {P}_{MAX} - {P}_{MIN} )}{{R}_{1} + {R}_{2}} \qquad ( 9 )$$

The above mathematical model depends on the battery voltage and no other characteristics of the batteries. Moreover, the function and mathematical model are independent of the battery chemistry, such as alkaline battery. Therefore, it is a function of the applied voltage and not the battery type.

Effectiveness of the techniques and systems as described in this specification can be verified using a joystick device by leaving the device “on” for the entire battery life cycle, and to detect the joystick's center reading throughout the battery life cycle. Similarly, the joystick's range of motion can be detected throughout the entire battery life to determine whether the range of motion varies with declining raw battery voltage V_{BATT}. The prediction model as described in this specification can enable the joystick to maintain a consistent center reading and range of motion even as the raw voltage of the battery V_{BATT}.

The function f(V_{BATT}) to estimate V_{DD}_{_{—}}_{ANALOG} based on V_{BATT} may not be exact due to minor variations between devices of the same design. To compensate for such variations from device to device in the case of a joystick, a dead zone around the joystick's center position can be added to the computed position to mask the minute inaccuracy from the end user.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a tangible program carrier for execution by, or to control the operation of, data processing apparatus. The tangible program carrier can be a computer readable medium. The computer readable medium can be a machine-readable storage device, a machine-readable storage substrate, a memory device, a composition of matter effecting a machine-readable propagated signal, or a combination of one or more of them.

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, or declarative or procedural languages, and it can be deployed in any form, including as a stand alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, input from the user can be received in any form, including acoustic, speech, or tactile input.

Embodiments of the subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described is this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

While this specification contains many specifics, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results.

Only a few implementations and examples are described and other implementations, enhancements and variations can be made based on what is described and illustrated in this application.

Moreover, the methods to provide data input, device control or game control may be performed in a different order and still achieve desirable results. Accordingly, other implementations are within the scope of the following claims.

What is claimed is:

1. A method comprising:
identifying a characteristic curve for a voltage regulating component;
detecting a raw voltage value of a battery associated with the voltage regulating component;
generating a mathematical model based on the identified characteristic curve; and
predicting a value of a voltage output of the voltage regulating component by using the generated mathematical model to convert the detected raw voltage value of the battery.

2. The method of claim 1, further comprising:
monitoring the detected raw voltage value of the battery throughout a life of the battery to detect a change in the detected raw voltage value; and
recalculating based on the detected change.

3. The method of claim 1, wherein predicting the value comprises predicting the value of the voltage output of the voltage regulating component that is powering an electronic component associated with the voltage regulating component.

4. The method of claim 3, wherein predicting the value comprises predicting the value of the voltage output of the voltage regulating component used to power the electronic component that includes a user input component.

5. The method of claim 3, furthering comprising calculating an output voltage at a terminal of a position sensing component based on the predicted value of the voltage output of the voltage regulating component, wherein the calculated output voltage represents a measure of a position for the motion sensing component.

6. The method of claim 5, wherein calculating the output voltage comprises calculating an output voltage at a terminal of a potentiometer based on the predicted value of the voltage output of the voltage regulating component, wherein the calculated output voltage represents a measure of a position for the potentiometer.

7. The method of claim 5, wherein calculating the output voltage comprises calculating an output voltage at a terminal of an accelerometer based on the predicted value of the voltage output of the voltage regulating component, wherein the calculated output voltage represents a measure of a position for the accelerometer.

8. A computer program product, embodied on a computer readable medium, operable to cause a data processing apparatus to perform operations comprising:
identifying a characteristic curve for a voltage regulating component;
detecting a raw voltage value of a battery associated with the voltage regulating component;
generating a mathematical model based on the identified characteristic curve; and
predicting a value of a voltage output of the voltage regulating component by using the generated mathematical model to convert the detected raw voltage value of the battery.

9. The computer program product of claim 8, further operable to cause a data processing apparatus to perform operations comprising:
monitoring the detected raw voltage value of the battery throughout a life of the battery to detect a change in the detected raw voltage value; and
recalculating based on the detected change.

10. The computer program product of claim 8, operable to cause a data processing apparatus to perform operations comprising predicting the value of the voltage output used to power an electronic component associated with the voltage regulating component or power converting component.

11. The computer program product of claim 10, operable to cause a data processing apparatus to perform operations comprising predicting the value of the voltage output used to power a user input component.

12. The computer program product of claim 10, operable to cause a data processing apparatus to perform operations comprising calculating an output voltage at a terminal of a position sensing component based on the predicted value of the voltage output of the voltage regulating component, wherein the calculated output voltage represents a measure of a position for the position sensing component.

13. The computer program product of claim 12, operable to cause a data processing apparatus to perform operations comprising calculating an output voltage at a terminal of a accelerometer based on the predicted value of the voltage output of the voltage regulating component, wherein the calculated output voltage represents a measure of a position for the accelerometer.

14. The computer program product of claim 12, operable to cause a data processing apparatus to perform operations comprising calculating an output voltage at a terminal of a potentiometer based on the predicted value of the voltage output of the voltage regulating component, wherein the calculated output voltage represents a measure of a position for the potentiometer.

15. A device comprising:
a battery;
a voltage regulating component connected to the battery; and
a processor connected to the battery and the voltage regulating component, wherein the processor is configured to process software or firmware to perform operations comprising
identify a characteristic curve for the voltage regulating component;
detect a raw voltage value of the battery connected to the voltage regulating component;
process a mathematical model generated based on the identified characteristic curve; and
predict a value of a voltage output of the voltage regulating component by using the processed mathematical model to convert the detected raw voltage value of the battery.

16. The device of claim 15, wherein the processor is further operable to
monitor the detected raw voltage value of the battery throughout a life of the battery to detect a change in the detected raw voltage value; and
recalculating based on the detected change.

17. The device of claim 15, further comprising an electronic component connected to the voltage regulating component; and wherein the processor is further operable to predict the value of the voltage output used to power the electronic component associated with the voltage regulating component.

18. The device of claim 17, wherein the processor is operable to predict the value of the voltage output used to power the electronic component including a user input component.

19. The device of claim 17, wherein the electronic component includes a position sensing component; and the processor is operable to calculate an output voltage at a terminal of the position sensing component based on the predicted value of the voltage output of the voltage regulating component, wherein the calculated output voltage represents a measure of a position for the position sensing component.

20. The device of claim 19, wherein the position sensing component includes a potentiometer; and the processor is operable to calculate an output voltage at a terminal of the potentiometer based on the predicted value of the voltage output of the voltage regulating component, wherein the calculated output voltage represents a measure of a position for the potentiometer.

21. The device of claim 19, wherein the position sensing component includes an accelerometer; and the processor is operable to calculate an output voltage of an accelerometer based on the predicted value of the voltage output of the voltage regulating component, wherein the calculated output voltage represents a measure of a position for the accelerometer.

22. The device of claim 15, wherein the voltage regulating component comprise a linear voltage regulator.

23. The device of claim 15, wherein the power converting component comprises an analog to digital converter.

24. The device of claim 15, wherein the power converting component comprises a direct current to direct current converter.
